(19) United States
(12) Patent Application Publication
(10) Pub. No.: US 2024/0186178 A1
(43) Pub. Date: Jun. 6, 2024

(54) WORDLINE CONTACT FORMATION FOR NAND DEVICE

(71) Applicant: Applied Materials, Inc., Santa Clara, CA (US)

(72) Inventors: HsiangYu LEE, Cupertino, CA (US); Pradeep SUBRAHMANYAN, Cupertino, CA (US); Changwoo SUN, San Jose, CA (US)

(73) Assignee: Applied Materials, Inc., Santa Clara, CA (US)

(21) Appl. No.: 18/523,401

(22) Filed: Nov. 29, 2023

Related U.S. Application Data
(60) Provisional application No. 63/429,851, filed on Dec. 2, 2022.

(51) Int. Cl. H01L 21/768; H01L 23/522

(52) U.S. Cl. CPC H01L 21/76816; H01L 21/76831; H01L 23/5226

(57) ABSTRACT

Disclosed are approaches for direct wordline contact formation for 3-D NAND devices. One method may include providing a film stack including a plurality of alternating first layers and second layers, and forming a plurality of contact openings in the film stack, wherein each contact opening is formed to a different etch depth relative to an upper surface of the film stack. The method may further include depositing a liner over the film stack including within each of the contact openings, removing the first layers to form a plurality of wordline openings in the film stack, and forming a plurality of wordlines by depositing a first conductive material within the wordline openings. The method may further include removing the liner from a bottom of each contact opening, and depositing a second conductive material within the contact openings to form a plurality of wordline contacts.

### RELATED APPLICATION

This application claims priority to U.S. provisional patent application Ser. No. 63/429,851, filed on Dec. 2, 2022, entitled “Wordline Contact Formation for NAND Device,” which is incorporated herein by reference in its entirety.

### FIELD

The present embodiments relate to processing of NAND devices and, more particularly, to approaches for direct wordline contact formation for 3D NAND devices.

### BACKGROUND

In accordance with current substrate (e.g., wafer) manufacturing approaches, etch speed, etch profile, and etch selectivity are optimized to lower manufacturing cost and increase circuit element density on a substrate. Etch features, such as memory holes, continue to shrink in size and/or increase in aspect ratio (e.g., ratio of depth to width of a feature), however. For example, in three dimensional (3D) NAND device manufacturing, substrates can include up to 96 layers and can extend up to 128 layers. Additionally, an aspect ratio of a memory hole, for example, can be between 100 to 200 with a memory hole depth ranging from about 6 μm to 8 μm, thus making memory hole etching one of the most critical and challenging steps when manufacturing 3D NAND devices. For example, such high aspect ratio etching not only requires high etching speed and high etching selectivity, e.g., to mask material on a substrate, but it also requires a straight profile without bowing and twisting, no under-etch and minimum micro-loading, minimum aspect ratio dependent etching (ARDE), and uniformity across the entire substrate (e.g., critical dimension (CD) variation of 3σ<1%).

When manufacturing 3D NAND devices having a staircase arrangement of layers, wordline landing pad formation is defined first through staircase formation (e.g., lithography and etch steps) and/or a chop process in which multiple layers are etched down, followed by a staircase area gap fill. However, selectivity margin during wordline contact etching remains a challenge.

It is with respect to these and other considerations that the present disclosure is provided.

### SUMMARY OF THE DISCLOSURE

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In view of the foregoing, a method may include providing a film stack including a plurality of alternating first layers and second layers, and forming a plurality of contact openings in the film stack, wherein each contact opening of the plurality of contact openings is formed to a different etch depth relative to an upper surface of the film stack. The method may further include depositing a liner over the film stack including within each contact opening of the plurality of contact openings, removing the first layers to form a plurality of wordline openings in the film stack, and forming a plurality of wordlines by depositing a first conductive material within the plurality of wordline openings. The method may further include removing the liner from a bottom of each contact opening of the plurality of contact openings, and depositing a second conductive material within the plurality of contact openings to form a plurality of wordline contacts.

In some approaches, a system may include a processor and a memory storing instructions executable by the processor to: form a film stack including a plurality of alternating first layers and second layers, form a plurality of contact openings in the film stack, wherein each contact opening of the plurality of contact openings is formed to a different etch depth relative to an upper surface of the film stack, deposit a liner over the film stack including within each contact opening of the plurality of contact openings, remove the first layers to form a plurality of wordline openings in the film stack, form a plurality of wordlines by depositing a first conductive material within the plurality of wordline openings, remove the liner from a bottom of each contact opening of the plurality of contact openings, and deposit a second conductive material within the plurality of contact openings to form a plurality of wordline contacts.

In some approaches, a memory device may include a stack of layers including a plurality of alternating first layers and wordlines oriented horizontally, and a plurality of contact openings formed vertically through the stack of layers, wherein each contact opening of the plurality of contact openings extends to an upper surface of the stack of layers, and wherein each contact opening of the plurality of contact openings is formed to a different etch depth relative to the upper surface of the film stack. The device may further include a wordline contact formed within each contact opening of the plurality of contact openings.

### BRIEF DESCRIPTION OF THE DRAWINGS

The accompanying drawings illustrate exemplary approaches of the disclosure, including the practical application of the principles thereof, as follows:

FIG. 1 illustrates a side cross-sectional view of a patterned first masking layer over a stack of alternating first and second layers of an exemplary device, according to embodiments of the present disclosure;

FIG. 2 illustrates a side cross-sectional view of a first set of contact openings formed in the stack of alternating first and second layers of the exemplary device, according to embodiments of the present disclosure;

FIG. 3 illustrates a side cross-sectional view of a patterned second masking layer over the stack of alternating first and second layers of the exemplary device, according to embodiments of the present disclosure;

FIG. 4 illustrates a side cross-sectional view of a second set of contact openings formed in the stack of alternating first and second layers of the exemplary device, according to embodiments of the present disclosure;

FIG. 5 illustrates a side cross-sectional view of a patterned third masking layer over the stack of alternating first and second layers of the exemplary device, according to embodiments of the present disclosure;

FIG. 6 illustrates a side cross-sectional view of a third set of contact openings formed in the stack of alternating first and second layers of the exemplary device, according to embodiments of the present disclosure;

FIG. 7 illustrates a side cross-sectional view of a liner formed within the plurality of contact openings, according to embodiments of the present disclosure;

FIG. 8 illustrates a side cross-sectional view of the exemplary device following removal of the second layers, according to embodiments of the present disclosure;

FIG. 9 illustrates a side cross-sectional view of the exemplary device following formation of a plurality of wordlines, according to embodiments of the present disclosure;

FIG. 10 illustrates a side cross-sectional view of the exemplary device after the liner is removed from a bottom of each of the plurality of contact openings, according to embodiments of the present disclosure;

FIG. 11 illustrates a side cross-sectional view of the exemplary device after formation of a plurality of contacts, according to embodiments of the present disclosure;

FIG. 12A illustrates a top view of a NAND device including a plurality of groups of contacts formed therein, according to embodiments of the present disclosure;

FIG. 12B illustrates a side cross-sectional view of a contact from a first group of contacts of the plurality of groups of contacts of the NAND device, according to embodiments of the present disclosure;

FIG. 12C illustrates a side cross-sectional view of a contact from a second group of contacts of the plurality of groups of contacts of the NAND device, according to embodiments of the present disclosure;

FIG. 12D illustrates a side cross-sectional view of a contact from a third group of contacts of the plurality of groups of contacts of the NAND device, according to embodiments of the present disclosure;

FIG. 12E illustrates a side cross-sectional view of a portion of the contact from the third group of contacts of the plurality of groups of contacts of the NAND device, according to embodiments of the present disclosure;

FIG. 12F illustrates a side cross-sectional view of a contact from a fourth group of contacts of the plurality of groups of contacts of the NAND device, according to embodiments of the present disclosure;

FIGS. 13A-13D illustrate side perspective views of an exemplary device during formation of a plurality of contact openings, according to embodiments of the present disclosure;

FIG. 14 is a schematic diagram of an example system according to embodiments of the present disclosure; and

FIG. 15 depicts a process flow of a method for forming the exemplary device, according to embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein are directed to 3-D NAND direct wordline contact-last integration techniques to minimize aspect ratio dependent etching. Direct wordline contact techniques of the present disclosure can reduce multiple conventional processing steps (e.g., staircase formation lithography and etching, chop lithography and etching, and staircase area gapfill deposition and planarization), and thus provides significant throughput and cost benefits. Furthermore, by forming wordline contact openings before wordline metal deposition, contact metal selectivity is improved and the use of stop layers may be eliminated. Still furthermore, the direct wordline, contact last approach of the present disclosure varies contact opening dimensions to compensate for aspect ratio dependent etching, and to mitigate wordline contact stress by combining contact metal and oxide deposition for a large contact opening gapfill.

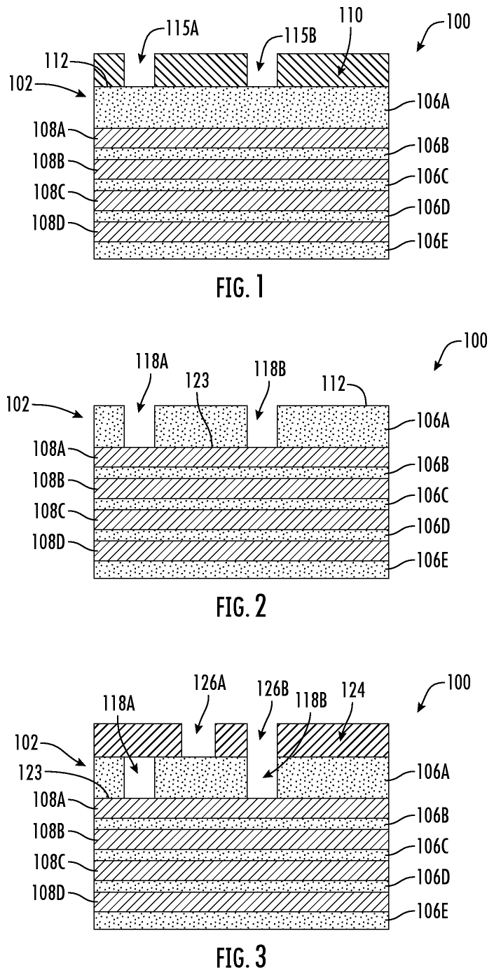

FIG. 1 illustrates a perspective view of a memory device (hereinafter “device”) 100 at an early stage of processing, according to one or more embodiments described herein. The device 100 may include a film stack 102 having a plurality of alternating horizontal first layers 106A-06E and second layers 108A-08D stacked atop one another. The film stack 102 may be a part of a memory cell device, such as a three-dimensional (3D) memory device (e.g., NAND). Although non-limiting, the first layers 106 may be a dielectric material, such as silicon oxide (SiO), and the second layers 108 may be a second dielectric material, such as silicon nitride. In other embodiments, suitable dielectric materials for the first layers 106 and/or the second layers 108 may include silicon oxynitride, silicon carbide, silicon oxycarbide, titanium nitride, composite of oxide and nitride, at least one or more oxide layers sandwiching a nitride layer, and combinations thereof, among others.

As further shown, the device 100 may include a first masking layer 110 formed directly atop an upper surface 112 of the film stack 102. The first masking layer 110 may be a photoresist layer including a set (i.e., one or more) of first mask openings 115A, 115B formed (e.g., etched) therein. As shown, the first mask openings 115A, 115B may be formed selective to the upper surface 112 of the film stack 102.

FIG. 2 demonstrates a set of first contact holes or openings 118A, 118B formed through a top layer of the film stack 102. In the embodiment shown, the first contact openings 118A, 118B are formed through the uppermost first layer 106A, which is exposed within the first mask openings 115A, 115B of the first masking layer 110. The first contact openings 118A, 118B may be etched selective to an upper surface 123 of second layer 108A.

As demonstrated in FIG. 3, a second masking layer 124 may then be formed over the film stack 102 and etched to form a set of second mask openings 126A, 126B therein. As shown, the second masking layer 124 may cover the first contact opening 118A, while the second mask opening 126B may be aligned with first contact opening 118B. The mask opening 126A may be formed between the first contact openings 118A, 118B.

As demonstrated in FIG. 4, the film stack 102 may again be etched to form a set of third contact openings 128A, 128B. The etch may be performed to the device 100 while the second masking layer 124 is present, which is subsequently removed. As such, the first contact opening 118A is generally unaffected by this etch step. The third contact opening 128A is formed through the first layer 106A, the second layer 108A, and the first layer 106B. The third contact opening 128A may extend to an upper surface 130 of the second layer 108B. Meanwhile, the third contact opening 128B is formed through the first layer 106A, the second layer 108A, the first layer 106B, the second layer 108B, and the first layer 106C. The third contact opening 128B may extend to an upper surface 131 of the second layer 108C. As demonstrated, the third contact openings 128A and 128B extend to different depths relative to the upper surface 112 of the film stack 102.

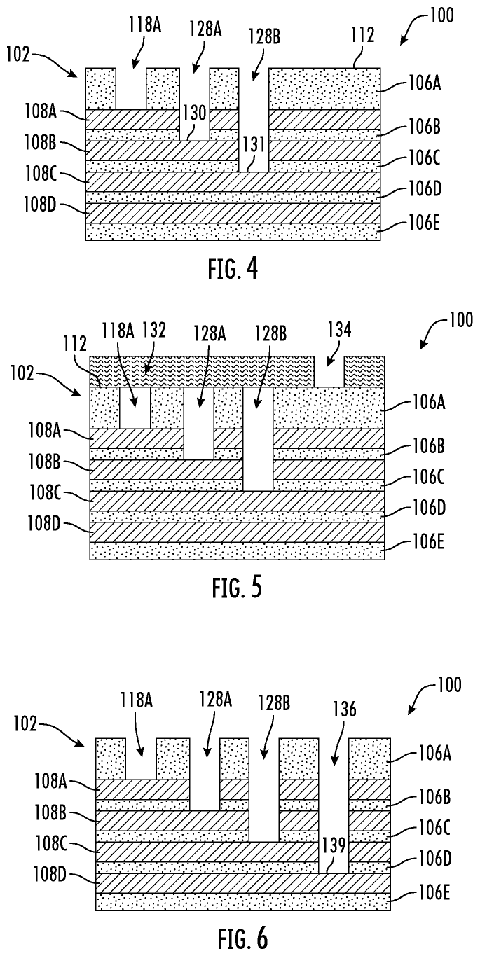

As demonstrated in FIG. 5, a third masking layer 132 may then be formed over the film stack 102 and etched to form a third mask opening 134 therein. As shown, the third masking layer 132 may cover the first contact opening 118A, as well as the third contact openings 128A, 128B. The third mask opening 134 may be formed selective to the upper surface 112 of the film stack 102.

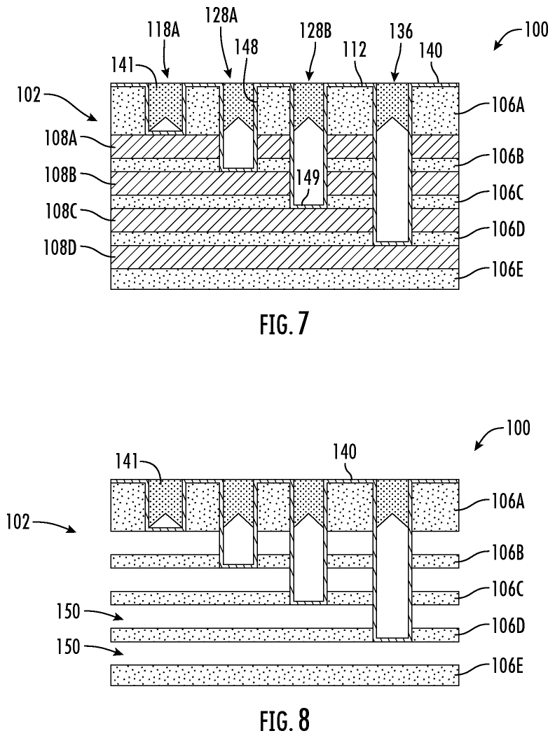

As demonstrated in FIG. 6, the film stack 102 may again be etched to form a fourth contact opening 136. The etch may be performed to the device 100 while the third masking layer 132 is present, which is then removed. As such, the first contact opening 118A and the third contact openings 128A, 128B are generally unaffected during formation of the fourth contact opening 136. The fourth contact opening 136 is formed through first layers 106A 106D and through second layers 108A-08C. The fourth contact opening 136 may extend to an upper surface 139 of the second layer 108D. As demonstrated, the first contact opening 118A, the third contact opening 128A, the third contact opening 128B, and the fourth contact opening 136 extend to different depths relative to the upper surface 112 of the film stack 102. The masking and etch steps may repeat depending on the number of layers present in the film stack 102. It will be appreciated that the device 100 may include a greater number of layers in other examples.

As demonstrated in FIG. 7, a liner 140 may then be formed over the device 100, including within each of the first contact opening 118A, the third contact opening 128A, the third contact opening 128B, and the fourth contact opening 136 (hereinafter referred to collectively as the plurality of contact openings). In some embodiments, the liner 140 may be an oxide layer (e.g., SiO, AlO, etc.), which is formed (e.g., via atomic layer deposition (ALD)) along the upper surface 112 of the film stack 102, and along a sidewall 148 and bottom 149 of the plurality of contact openings. As further shown, a gapfill 141 may also be formed within each of the plurality of contact openings. Although non-limiting, the gapfill 141 may be a sacrificial carbon film.

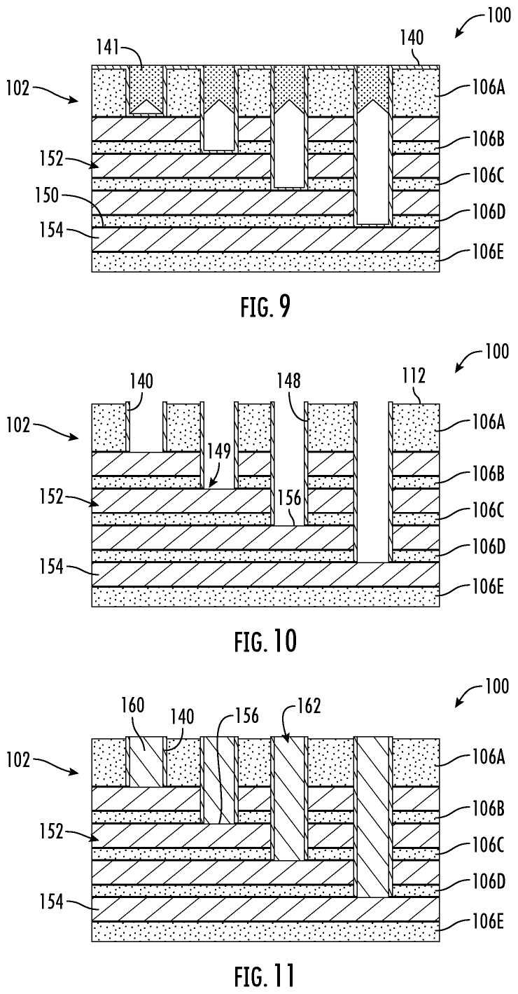

As demonstrated in FIG. 8, the second layers 108A-08D have been removed from the film stack 102, e.g., by a horizontal wet etch process, to form a plurality of wordline openings 150 therein. The first layers 106A-06E and the liner 140 are generally unaffected by the wet etch. A plurality of wordlines 152 may then be formed in the device 100, as demonstrated in FIG. 9, by depositing a first conductive material 154 (e.g., tungsten (W) or molybdenum (Mo)) within the plurality of wordline openings 150. The gapfill 141 and the liner 140 may then be removed, as shown in FIG. 10, wherein the liner 140 is removed from the upper surface 112 of the film stack 102 and from the bottom 149 of the plurality of contact openings. In some embodiments, the liner 140 may be vertically etched to expose an upper surface 156 of one or more of the plurality of wordlines 152. As shown, the liner 140 remains along the sidewall 148 of the plurality of contact openings.

As demonstrated in FIG. 11, a second conductive material 160 may be deposited within the plurality of contact openings to form a plurality of wordline contacts 162. In some embodiments, the second conductive material 160 may be tungsten, which is deposited together with titanium nitride (TiN), atop the upper surface 156 of the plurality of wordlines 152. The second conductive material 160 may be separated from the first layers 106A-06E by the liner 140 along the sidewall 148 of the plurality of contact openings.

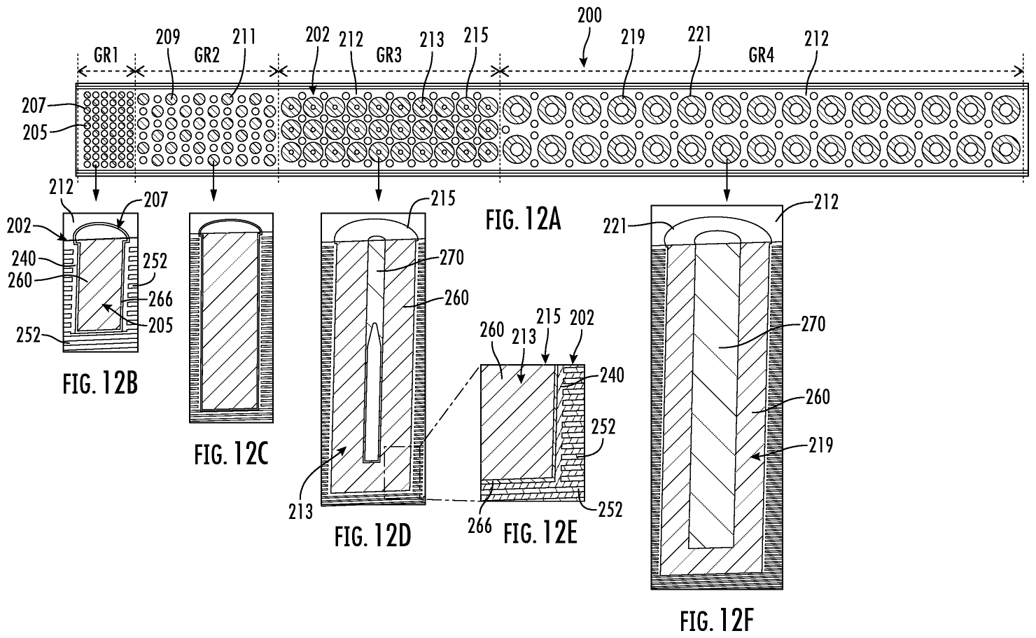

FIG. 12A is a top view of a device 200 including a plurality of groups of wordline contacts formed in a film stack 202. For example, group one (“GR1”) may include a first plurality of wordline contacts 205 formed in a first plurality of contact openings 207, group two (“GR2”) may include a second plurality of wordline contacts 209 formed in a second plurality of contact openings 211, group three (“GR3”) may include a third plurality of wordline contacts 213 formed in third plurality of contact openings 215, group four (“GR4”) may include a fourth plurality of wordline contacts 219 formed in a fourth plurality of contact openings 221, and so on.

Each of the first, second, third, and fourth plurality of wordline contacts 205, 209, 213, and 219 may be formed using the approaches shown in FIGS. 1-11 and described above. For example, as more clearly shown in FIG. 12B and FIG. 12E, the device 200 may include a plurality of wordlines 252 formed within the film stack 202, and a liner 240 formed within the first plurality of contact openings 207 and the third plurality of contact openings 215. A contact liner 266 and a conductive material 260 may be deposited within the first plurality of contact openings 207 and the third plurality of contact openings 215 to form the first plurality of wordline contacts 205 and the third plurality of wordline contacts 213, respectively. In various embodiments, the conductive material 260 may be W, tungsten silicide (WSi), tungsten polysilicon (W/poly), tungsten alloy, tantalum (Ta), titanium (Ti), copper (Cu), ruthenium (Ru), nickel (Ni), cobalt (Co), chromium (Cr), iron (Fe), manganese (Mn), aluminum (Al), hafnium (Hf), vanadium (V), molybdenum (Mo), palladium (Pd), gold (Au), silver (Au), platinum (Pt), alloys thereof, or combinations thereof. Meanwhile, the contact liner 266 may be a metal nitride layer or metal silicon nitride layer, such as TiN, tantalum nitride (TaN), TaSiN, TiSiN and combinations thereof, among others.

As demonstrated, the first, second, third, and fourth plurality of wordline contacts 205, 209, 213, and 219 may be separated into various groups with different CDs to compensate for different aspect ratios of the respective contact openings 207, 211, 215, and 221 of the device 200. For example, as demonstrated in FIG. 12B-12D, the first plurality of contact openings 207 of GR1 and the second plurality of contact openings 211 of GR2 may be formed to different etch depths relative to an upper surface 212 of the film stack 202, while the third plurality of contact openings 215 of GR3 may be formed to a different (i.e., greater) etch depth, relative to the upper surface 212 of the film stack 202, than the second plurality of contact openings 211. As further shown in FIG. 12F, the fourth plurality of contact openings 221 of GR4 may be formed to a greater etch depth than the third plurality of contact openings 215. As a result, an average length/depth of the wordline contacts in the device 200 may increase between GR1 and GR4. Furthermore, in the embodiment shown, an average diameter of the third plurality of contact openings 215 is greater than an average diameter of the second plurality of contact openings 211, which is greater than an average diameter of the first plurality of contact openings 207. Each wordline contact may extend entirely to the upper surface 212 of the film stack 202, eliminating the need for a staircase arrangement for the film stack 202. Said another way, the upper surface 212 of the film stack 202 in GR1 is coplanar with the upper surface 212 of the film stack 202 in GR4.

In some embodiments, as demonstrated in FIG. 12D and FIG. 12F, a dielectric gap-fill 270 may be formed within the third plurality of contact openings 215 and the fourth plurality of contact openings 221. The dielectric gap-fill 270 may be beneficial for larger contact holes to reduce the wafer stress and cost of ownership. As shown, the gap-fill 270 may be surrounded by the conductive material 260 of the third plurality of wordline contacts 213 and the fourth plurality of wordline contacts 219, respectively. Although non-limiting, the dielectric gap-fill 270 may be SiO2, SiN, SiON, or other suitable dielectric materials, and may be formed by suitable deposition process, such as CVD, ALD, a sputtering process, or a coating process.

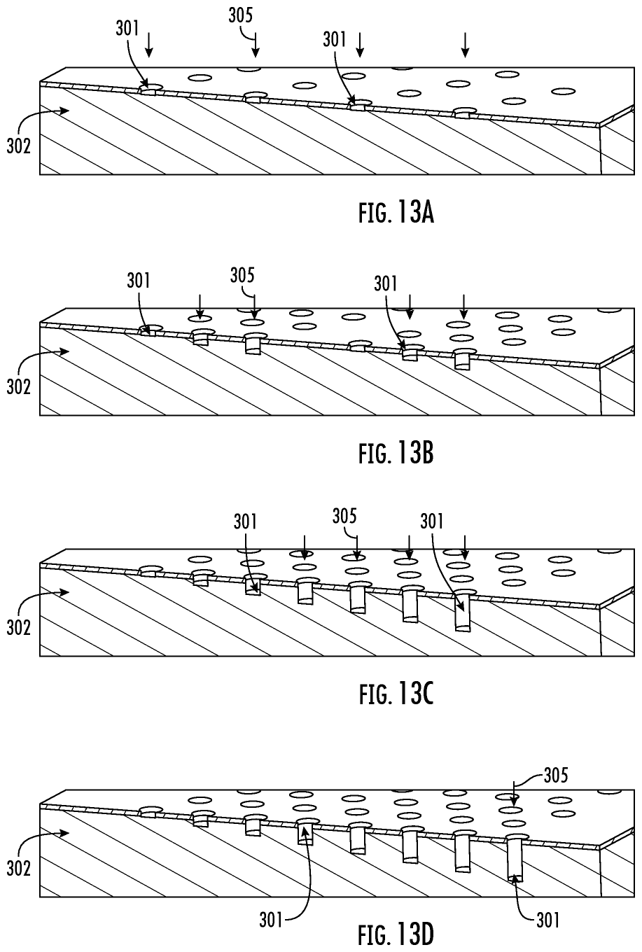

FIG. 13 further demonstrates formation of a plurality of wordline contact openings 301 in a film stack 302 according to the approaches described herein. The plurality of contact openings 301 may be formed (e.g., etched 305) using the same or similar approaches used to form the wordline contact openings of devices 100 and/or 200. In the embodiment shown, a total of 360 ON pairs may be present in the device 300. For example, as shown in Table 1., below, nine (9) etch/lithography steps are used to form the 360 pairs.

TABLE 1

| | Etch down ON pairs |
|---|---|
| Litho/Etch process step | Top tier |
| 1 | 1 |
| 2 | 2 |
| 3 | 4 |
| 4 | 8 |
| 5 | 16 |
| 6 | 32 |
| 7 | 64 |
| 8 | 128 |
| 9 | 105 |

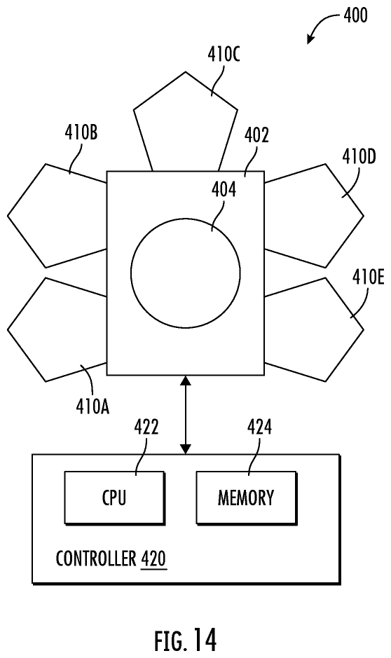

FIG. 14 shows a schematic of an example system/apparatus 400 according to embodiments of the disclosure. Operation of the system 400 will be described with reference to the device 100. In some embodiments, the system 400 may be a cluster tool operable to perform processes necessary to form the device 100 and the device 200 described herein. Although non-limiting, the system 400 may include at least one central transfer station/chamber 402 and one or more robots 404 within the transfer station/chamber 402, wherein the robot 404 is operable to move a robot blade and a wafer to and from each of a plurality of processing chambers 410A-410N connected with, or positioned adjacent to, the transfer station/chamber 402. In some embodiments, the system 400 may include any variety of suitable chambers including, but not limited to, a first deposition chamber 410A, a first etch chamber 410B, a second deposition chamber 410C, a second etch chamber 410D, and a third deposition chamber 410E. The first deposition chamber 410A, the second deposition chamber 410C, and the third deposition chamber 410E may include one or more of an atomic layer deposition chamber, a plasma enhanced atomic layer deposition chamber, a chemical vapor deposition chamber, a plasma enhanced chemical vapor deposition chamber, or a physical deposition. The particular arrangement of process chambers and components can be varied depending on the cluster tool, and should not be taken as limiting the scope of the disclosure. For example, in alternative embodiments, only a single deposition chamber and/or only a single etch chamber is present in the system 400. In another example, one or more of the deposition chambers may include multiple process regions within a same chamber, which permits a common supply of gases, common pressure control, and common process gas exhaust/pumping. Modular design of the system enables rapid conversion from one configuration to any other.

In some embodiments, the first deposition chamber 410A may be used to deposit the film stack 102 as alternating first layers 106 and second layers 108, and to deposit the plurality of masking layers (e.g., the first masking layer 110, the second masking layer 124, and the third masking layer 132) over the film stack 102.

The first etch chamber 410B may be used to etch the plurality of masking layers and to form the plurality of contact openings (e.g., the first contact opening 118A, the third contact opening 128A, the third contact opening 128B, and the fourth contact opening 136) in the film stack 102, wherein each contact opening of the plurality of contact openings is formed to a different etch depth relative to the upper surface 112 of the film stack 102.

The second deposition chamber 410C may be used to deposit the liner 140 over the film stack 102, including within each contact opening of the plurality of contact openings, while the second etch chamber 410D may be used to remove the first layers 106 to form the plurality of wordline openings 150 in the film stack 102.

The third deposition chamber 410E may be used to form the plurality of wordlines 152 by depositing the first conductive material 154 within the plurality of wordline openings 150, while the second etch chamber 410D may be used to punch through the liner 140 along the bottom 149 of each contact opening of the plurality of contact openings.

The third deposition chamber 410E (or another deposition chamber) may be further used to deposit the second conductive material 160 within the plurality of contact openings to form the plurality of wordline contacts 162.

A system controller 420 is in communication with the robot 404, the transfer station/chamber 402, and the plurality of processing chambers 410A-410E. The system controller 420 can be any suitable component that can control the processing chambers 410A-410E and robot(s) 404, as well as the processes occurring within the process chambers 410A-410E. For example, the system controller 420 can be a computer including a central processing unit 422, memory 424, suitable circuits/logic/instructions, and storage.

Processes or instructions may generally be stored in the memory 424 of the system controller 420 as a software routine that, when executed by the processor 422, causes the processing chambers 410A-410N to perform processes of the present disclosure. The software routine may also be stored and/or executed by a second processor (not shown) that is remotely located from the hardware being controlled by the processor 422. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 422, transforms the general purpose computer into a specific purpose computer (controller) that controls the chamber operation such that the processes are performed.

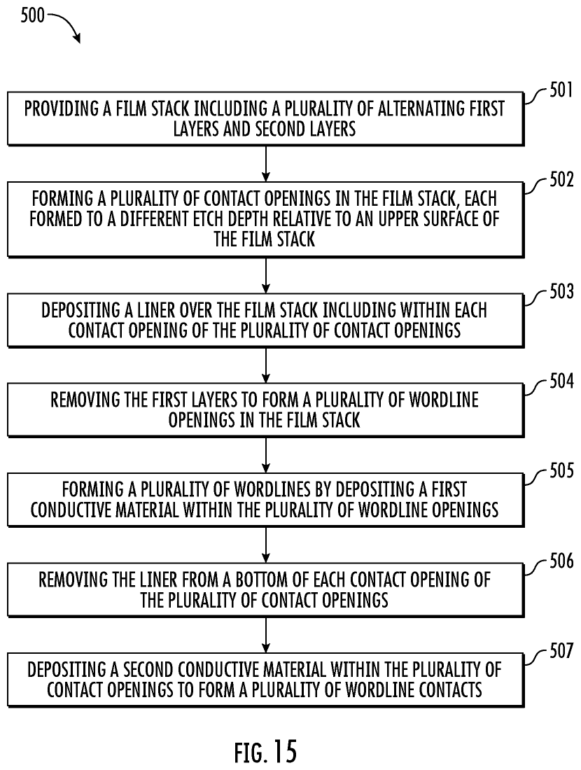

Turning now to FIG. 15, a process 500 according to embodiments of the present disclosure is shown. At block 501, the process 500 may include providing a film stack including a plurality of alternating first layers and second layers. In some embodiments, the first layers of the plurality of alternating first layers and second layers are a dielectric material, and the second layers of the plurality of alternating first layers and second layers are a dielectric material or a conductive material. In some embodiments, the first layers of the plurality of alternating first layers and second layers are silicon oxide, and the second layers of the plurality of alternating first layers and second layers are silicon nitride.

At block 502, the process 500 may include forming a plurality of contact openings in the film stack, wherein each contact opening of the plurality of contact openings is formed to a different etch depth relative to an upper surface of the film stack. In some embodiments, forming the plurality of contact openings in the film stack may include patterning a first set of openings through a first masking layer, and etching, through the first set of openings, a first set of contact openings of the plurality of contact openings. Forming the plurality of contact openings in the film stack may further include patterning a second set of openings through a second masking layer, wherein one opening of the second set of openings is aligned with one contact opening of the first set of contact openings, and etching, through the second set of openings, a second set of contact openings of the plurality of contact openings. Forming the plurality of contact openings in the film stack may further include patterning a third set of openings through a third masking layer, wherein the third masking layer is formed over the first and second sets of contact openings, and etching, through the third set of openings, a third set of contact openings of the plurality of contact openings. In some embodiments, a first depth of the first set of contact openings is less than a second depth of the second set of contact openings, and the second depth of the second set of contact openings is less than a third depth of the third set of contact openings.

At block 503, the process 500 may include depositing a liner over the film stack including within each contact opening of the plurality of contact openings.

At block 504, the process 500 may include removing the first layers to form a plurality of wordline openings in the film stack. In some embodiments, the wordline openings are formed using a lateral wet etch process.

At block 505, the process 500 may include forming a plurality of wordlines by depositing a first conductive material within the plurality of wordline openings. In some embodiments, the first conductive material is W or Mo.

At block 506, the process 500 may include removing the liner from a bottom of each contact opening of the plurality of contact openings. In some embodiments, removing the liner from the bottom of each contact opening of the plurality of contact openings exposes an upper surface of one or more of the plurality of wordlines. In some embodiments, the liner is removed from the bottom of each contact opening of the plurality of contact openings without removing the liner from a sidewall of each contact opening of the plurality of contact openings.

At block 507, the process 500 may include depositing a second conductive material within the plurality of contact openings to form a plurality of wordline contacts. In some embodiments, the second conductive material 160 may be W, which is deposited together with TiN, atop an upper surface of the plurality of wordlines.

In some embodiments, the process 500 may further include forming a second plurality of contact openings in the film stack, wherein each contact opening of the second plurality of contact openings is formed to a different etch depth relative to an upper surface of the film stack, wherein an average diameter of the second plurality of contact openings is greater than an average diameter of the first plurality of contact openings, and wherein an average depth of the second plurality of contact openings is greater than an average depth of the first plurality of contact openings. In some embodiments, the second plurality of contact openings may be formed adjacent the first plurality of contact openings. In some embodiments, the second plurality of contact openings may be formed simultaneously with the first plurality of contact openings.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
providing a film stack including a plurality of alternating first layers and second layers;
forming a plurality of contact openings in the film stack, wherein each contact opening of the plurality of contact openings is formed to a different etch depth relative to an upper surface of the film stack;
depositing a liner over the film stack including within each contact opening of the plurality of contact openings;
removing the first layers to form a plurality of wordline openings in the film stack;
forming a plurality of wordlines by depositing a first conductive material within the plurality of wordline openings;
removing the liner from a bottom of each contact opening of the plurality of contact openings; and
depositing a second conductive material within the plurality of contact openings to form a plurality of wordline contacts.

2. The method of claim 1, wherein forming the plurality of contact openings in the film stack comprises:
patterning a first set of openings through a first masking layer;
etching, through the first set of openings, a first set of contact openings of the plurality of contact openings;
patterning a second set of openings through a second masking layer, wherein one opening of the second set of openings is aligned with one contact opening of the first set of contact openings;
etching, through the second set of openings, a second set of contact openings of the plurality of contact openings;
patterning a third set of openings through a third masking layer, wherein the third masking layer is formed over the first and second sets of contact openings; and
etching, through the third set of openings, a third set of contact openings of the plurality of contact openings.

3. The method of claim 2, wherein a first depth of the first set of contact openings is less than a second depth of the second set of contact openings, and wherein the second depth of the second set of contact openings is less than a third depth of the third set of contact openings.

4. The method of claim 3, wherein the first layers of the plurality of alternating first layers and second layers are silicon oxide, and wherein the second layers of the plurality of alternating first layers and second layers are silicon nitride.

5. The method of claim 1, wherein the first layers of the plurality of alternating first layers and second layers are a dielectric material, and wherein the second layers of the plurality of alternating first layers and second layers are a dielectric material or a conductive material.

6. The method of claim 1, wherein removing the liner from the bottom of each contact opening of the plurality of contact openings exposes an upper surface of one or more of the plurality of wordlines.

7. The method of claim 1, wherein the liner is removed from the bottom of each contact opening of the plurality of contact openings without removing the liner from a sidewall of each contact opening of the plurality of contact openings.

8. The method of claim 1, further comprising forming a second plurality of contact openings in the film stack, wherein each contact opening of the second plurality of contact openings is formed to a different etch depth relative to an upper surface of the film stack, wherein an average diameter of the second plurality of contact openings is greater than an average diameter of the plurality of contact openings, and wherein an average depth of the second plurality of contact openings is greater than an average depth of the plurality of contact openings.

9. A system, comprising:
a processor;
a memory storing instructions executable by the processor to:
form a film stack including a plurality of alternating first layers and second layers;
form a plurality of contact openings in the film stack, wherein each contact opening of the plurality of contact openings is formed to a different etch depth relative to an upper surface of the film stack;
deposit a liner over the film stack including within each contact opening of the plurality of contact openings;
remove the first layers to form a plurality of wordline openings in the film stack;
form a plurality of wordlines by depositing a first conductive material within the plurality of wordline openings;
remove the liner from a bottom of each contact opening of the plurality of contact openings; and
deposit a second conductive material within the plurality of contact openings to form a plurality of wordline contacts.

10. The system of claim 9, wherein the instructions executable by the processor to form the plurality of contact openings in the film stack comprises:
patterning a first set of openings through a first masking layer;
etching, through the first set of openings, a first set of contact openings of the plurality of contact openings;
patterning a second set of openings through a second masking layer, wherein one opening of the second set of openings is aligned with one contact opening of the first set of contact openings;
etching, through the second set of openings, a second set of contact openings of the plurality of contact openings;
patterning a third set of openings through a third masking layer, wherein the third masking layer is formed over the first and second sets of contact openings; and
etching, through the third set of openings, a third set of contact openings of the plurality of contact openings.

11. The system of claim 10, wherein the instructions executable by the processor to form the plurality of contact openings in the film stack further comprises:
forming the first set of contact openings to a first depth;
forming the second set of contact openings to a second depth, wherein the second depth is greater than the first depth; and
forming the third set of contact openings to a third depth, wherein the third depth is greater than the second depth.

12. The system of claim 9, wherein the instructions executable by the processor to form the film stack including a plurality of alternating first layers and second layers comprises forming the first layers using a dielectric material, and forming the second layers using a dielectric material or a conductive material.

13. The system of claim 9, wherein the instructions executable by the processor to remove the liner from the bottom of each contact opening of the plurality of contact openings further comprises exposing an upper surface of one or more of the plurality of wordlines.

14. The system of claim 9, wherein the instructions executable by the processor to remove the liner from the bottom of each contact opening of the plurality of contact openings further comprises removing the liner from the bottom of each contact opening of the plurality of contact openings without removing the liner from a sidewall of each contact opening of the plurality of contact openings.

15. The system of claim 9, further comprising instructions executable by the processor to form a second plurality of contact openings in the film stack, wherein each contact opening of the second plurality of contact openings is formed to a different etch depth relative to an upper surface of the film stack, wherein an average diameter of the second plurality of contact openings is greater than an average diameter of the plurality of contact openings, and wherein an average depth of the second plurality of contact openings is greater than an average depth of the plurality of contact openings.

16. A memory device, comprising:
a stack of layers including a plurality of alternating first layers and wordlines oriented horizontally;
a plurality of contact openings formed vertically through the stack of layers, wherein each contact opening of the plurality of contact openings extends to an upper surface of the stack of layers, and wherein each contact opening of the plurality of contact openings is formed to a different etch depth relative to the upper surface of the film stack; and
a wordline contact formed within each contact opening of the plurality of contact openings.

17. The memory device of claim 16, further comprising a liner formed along a sidewall of each contact opening of the plurality of contact openings.

18. The memory device of claim 16, wherein a first depth of a first set of contact openings of the plurality of contact openings is less than a second depth of a second set of contact openings of the plurality of contact openings, and wherein the second depth of the second set of contact openings is less than a third depth of a third set of contact openings of the plurality of contact openings.

19. The memory device of claim 16, wherein the first layers of the stack of layers are a dielectric material, wherein the wordlines are a first conductive material, and wherein the wordline contacts are a third conductive material.

20. The memory device of claim 16, wherein each wordline is tungsten or molybdenum, and wherein each wordline contact is tungsten.
